(19) United States
(12) Patent Application Publication
(10) Pub. No.: US 2026/0018204 A1
(43) Pub. Date: Jan. 15, 2026

(54) ENHANCED DOUBLE DATA RATE INTERNAL WRITE LEVELING SCHEME

(71) Applicant: Micron Technology, Inc., Boise, ID (US)

(72) Inventor: Jongtae KWAK, Carrollton, TX (US)

(21) Appl. No.: 19/204,914

(22) Filed: May 12, 2025

Related U.S. Application Data
(60) Provisional application No. 63/669,912, filed on Jul. 11, 2024.

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

A memory device includes a first internal write leveling (IWL) circuit configured to evaluate a timing relationship between a pair of data strobe signals and a write command signal according to a first IWL scheme, and generate a first IWL result signal indicating whether the timing relationship satisfies a first IWL condition; a second IWL circuit configured to evaluate the timing relationship between the pair of data strobe signals and the write command signal according to a second IWL scheme, and generate a second IWL result signal indicating whether the timing relationship satisfies a second IWL condition, wherein the second IWL scheme is different from the first IWL scheme; and a combining circuit configured to receive the first IWL result signal and the second IWL result signal, and generate a final IWL result signal indicating whether the timing relationship satisfies both the first IWL condition and the second IWL condition.

### CROSS-REFERENCE TO RELATED APPLICATION

This patent application claims priority to U.S. Provisional Patent Application No. 63/669,912, filed on Jul. 11, 2024, entitled “ENHANCED DOUBLE DATA RATE INTERNAL WRITE LEVELING SCHEME,” and assigned to the assignee hereof. The disclosure of the prior application is considered part of and is incorporated by reference into this patent application.

### TECHNICAL FIELD

The present disclosure generally relates to memory devices, memory device operations, and, for example, to an enhanced double data rate (DDR) internal write leveling (IWL) scheme.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of performing an enhanced internal write leveling (IWL) scheme.

FIG. 2 is a diagram illustrating a memory device according to one or more implementations.

FIG. 3 shows diagrams of pulse captures according to one or more implementations.

FIG. 4 is a flowchart of an example method associated with an enhanced DDR IWL scheme.

### DETAILED DESCRIPTION

The memory industry needs a more reliable and robust internal write leveling scheme consistent with regular write operations to enhance synchronization accuracy between data and command signals during write operations in memory devices, such as dynamic random-access memory (DRAM) devices. Existing internal write leveling (IWL) calibration methods have limitations that hinder their effectiveness when considered individually. For example, some IWL calibration methods are utilized in a different voltage domain from a voltage domain in which write operations are performed, which may potentially introduce inaccuracies when applying the write leveling results to normal write operation scenarios. In addition, some existing IWL calibration methods may be limited by a gating accuracy of gating logic used to capture pulses of a data strobe signal, where a number of captured pulses is used for determining an optical setting for the write leveling. In addition, some existing IWL calibration methods may be performed in a same voltage domain in which write operations are performed, but may have accuracy limitations at decision boundaries (e.g., when an edge of a write command signal is too close for capturing a valid pulse of the data strobe signal). The accuracy limitations may result in obscured signal capture errors, misleadingly indicating successful synchronization while the subsequent normal write operation may fail due to the obscured signal capture errors. Consequently, the synchronization process is not effectively accommodated by existing IWL calibration methods.

Accordingly, one or more implementations disclosed herein provide a memory device that utilizes multiple IWL circuits. These IWL circuits evaluate the timing relationship between data strobe signals and a write command signal according to different IWL schemes to diversify an overall IWL operation to arrive at a more accurate IWL decision or result. The first IWL circuit may count a number of pulse toggles in gated data strobe signals, while the second IWL circuit may check for missing pulse toggles in the gated data strobe signals. In addition, the first IWL circuit may be arranged in a different voltage domain from a voltage domain in which write operations are performed, while the second IWL circuit may be arranged in a same voltage domain in which write operations are performed. Moreover, the second IWL circuit may be used in normal write operations (e.g., after IWL calibration is performed). Thus, the second IWL circuit may have a dual-use functionality, which may lead to more accurate IWL calibrations, since a result provided by the second IWL circuit during the IWL operation may be a more accurate representation of an actual write operation scenario. By combining the results of both IWL circuits using a combining circuit, the memory device may achieve a more accurate and more robust internal write leveling process. This reduces a likelihood of memory access errors (e.g., write errors) and improves the efficiency of the memory subsystem. Additionally, the solution ensures better synchronization between data and command signals, enhancing system stability and conserving processing resources.

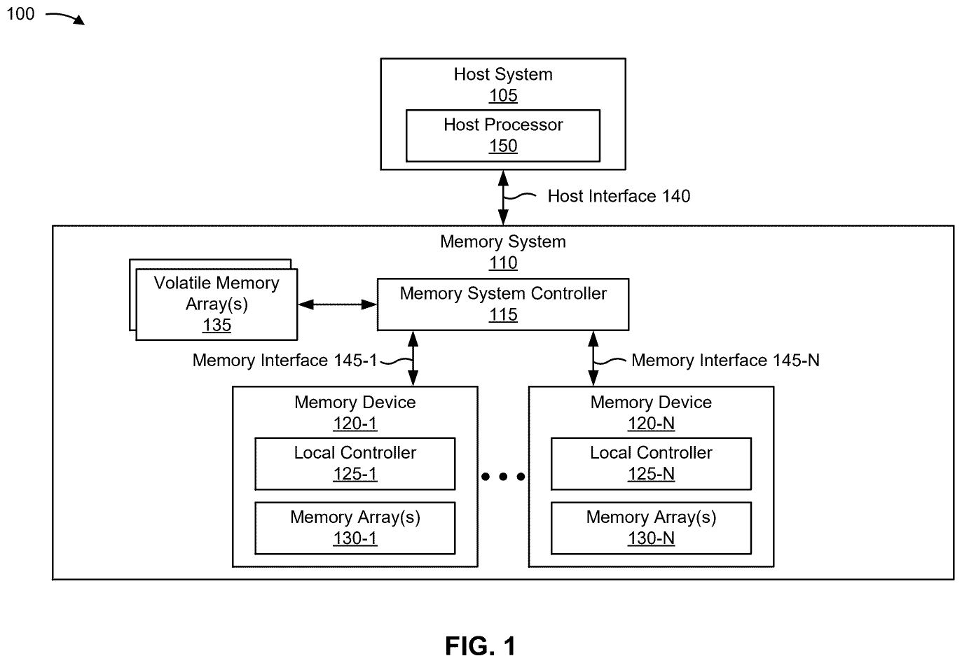

FIG. 1 is a diagram illustrating an example system 100 capable of performing an enhanced internal write leveling (IWL) scheme. For example, the IWL scheme may be used in DDR DRAM applications to increase write command and hand-shaking timing accuracy. Internal write leveling is a calibration process used in DDR DRAM applications to ensure that data is accurately written to memory modules of a memory device. IWL is particularly important in high-speed memory interfaces, such as DDR3, DDR4, and DDR5, where precise timing is critical for reliable data transfer. A purpose of write leveling is to align a clock signal and data strobe signals at memory cells. In high-speed DDR memory systems, data is transferred on both the rising and falling edges of the clock signal, which requires very precise timing. Variations in trace lengths and signal propagation delays can cause timing mismatches between the clock and data strobe signals. Write leveling may correct the timing mismatches to ensure that data is written correctly to the memory cells.

The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120. Each memory device 120 may include logic and/or other circuitry used for performing one or more calibration operations, such as IWL, and/or memory operations, such as read or write.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

For an IWL operation, the memory system controller 115 may initiate a write leveling process when the memory system 110 is powered on. This may occur during an initialization sequence of DRAM.

The memory system controller 115 may adjust a timing of the data strobe signals (DQS) relative to a write command signal to determine an optimum timing relationship between the write command signal and the DQS. The memory system controller 115 may send a series of write commands to one or more volatile memory arrays 135 while varying the timing of the DQS. A volatile memory array 135 may capture data using an internal clocking mechanism and may send feedback to the memory system controller 115 that indicates whether the timing relationship is acceptable (e.g., good) or unacceptable (e.g., bad) for accurate write operations. The memory system controller 115 may analyze the feedback to determine the optimal delay settings for the DQS for achieving accurate write operations. This involves identifying a point where data is sampled correctly without timing errors. Once the optimal timing is determined, the memory system controller 115 may program these delay settings into write leveling registers. The delay settings may ensure that the DQS are properly aligned with the write command signals during normal write operations.

In some implementations, one or more systems, devices, apparatuses, components, and/or controllers of FIG. 1 may include a first IWL circuit configured to evaluate a timing relationship between a pair of data strobe signals and a write command signal according to a first IWL scheme, and generate a first IWL result signal indicating whether the timing relationship satisfies a first IWL condition; a second IWL circuit configured to evaluate the timing relationship between the pair of data strobe signals and the write command signal according to a second IWL scheme, and generate a second IWL result signal indicating whether the timing relationship satisfies a second IWL condition, wherein the second IWL scheme is different from the first IWL scheme; and a combining circuit configured to receive the first IWL result signal and the second IWL result signal, and generate a final IWL result signal indicating whether the timing relationship satisfies both the first IWL condition and the second IWL condition.

In some implementations, one or more systems, devices, apparatuses, components, and/or controllers of FIG. 1 may include gating logic configured to receive a pair of data strobe signals and a write command signal, wherein the pair of data strobe signals includes a first data strobe signal and a second data strobe signal that is complementary to the first data strobe signal, wherein the gating logic is configured to capture a first number of captured pulses of the first data strobe signal based on a gating of the first data strobe signal by the write command signal, wherein the gating logic is configured to capture a second number of captured pulses of the second data strobe signal based on a gating of the second data strobe signal by the write command signal; a first IWL circuit is configured to indicate whether the first number of captured pulses matches an expected number of captured pulses, indicate whether the second number of captured pulses matches the expected number of captured pulses, and generate a first IWL result signal indicating whether a timing relationship between the pair of data strobe signals and the write command signal satisfies a first IWL condition based on the first number of captured pulses and the second number of captured pulses matching the expected number of captured pulses; a second IWL circuit is configured to indicate whether the first number of captured pulses matches the expected number of captured pulses, indicate whether the second number of captured pulses matches the expected number of captured pulses, and generate a second IWL result signal indicating whether the timing relationship satisfies a second IWL condition based on at least one of the first number of captured pulses or the second number of captured pulses matching the expected number of captured pulses; and a combining circuit configured to receive the first IWL result signal and the second IWL result signal, and generate a final IWL result signal indicating whether the timing relationship satisfies both the first IWL condition and the second IWL condition.

In some implementations, one or more systems, devices, apparatuses, components, and/or controllers of FIG. 1 may be configured to evaluate a timing relationship between a pair of data strobe signals and a write command signal according to a first IWL scheme; generate a first IWL result signal indicating whether the timing relationship satisfies a first IWL condition; evaluate the timing relationship between the pair of data strobe signals and the write command signal according to a second IWL scheme, wherein the second IWL scheme is different from the first IWL scheme; generate a second IWL result signal indicating whether the timing relationship satisfies a second IWL condition; and generate a final IWL result signal indicating whether the timing relationship satisfies both the first IWL condition and the second IWL condition.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

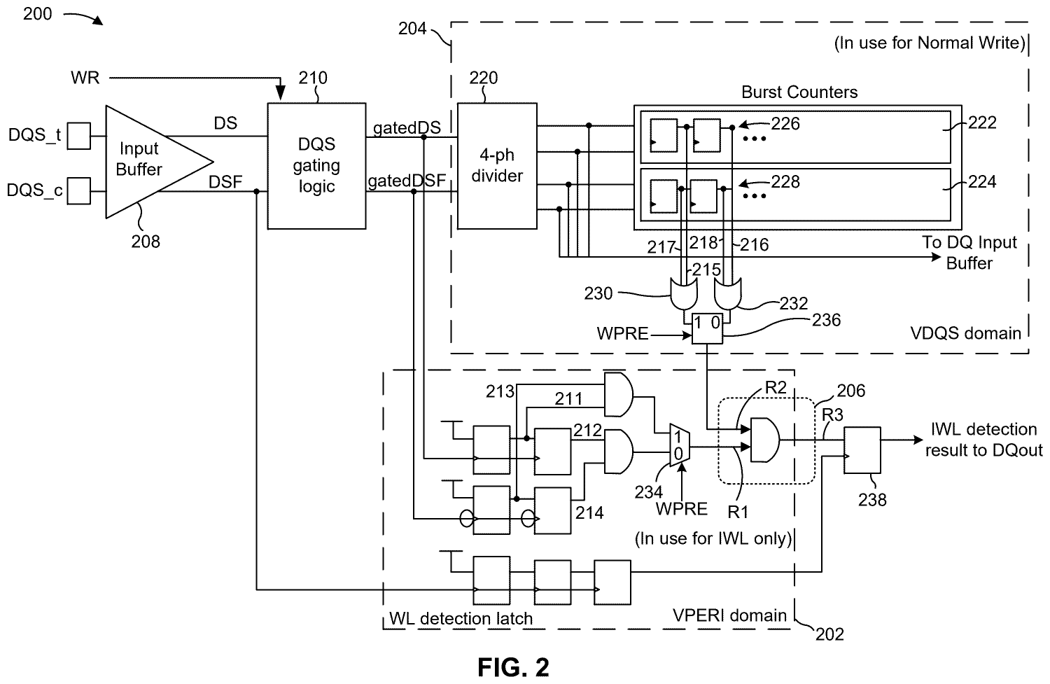

FIG. 2 is a diagram illustrating a memory device 200 according to one or more implementations. The memory device 200 may be a DRAM memory chip that may be implemented in the memory system 110 described in connection with FIG. 1. The memory device 200 may include a DDR interface for transferring data based on a DDR standard. For example, the memory device 200 may be coupled to a controller, such as the memory system controller 115, by a DDR interface. Thus, the memory device 200 may transfer data on a rising edge and a falling edge of a clock signal.

The memory device 200 may include a first IWL circuit 202 configured to evaluate a timing relationship between a pair of data strobe signals DQS_t and DQS_c and a write command signal WR according to a first IWL scheme, and generate a first IWL result signal R1 indicating whether the timing relationship satisfies a first IWL condition. The pair of data strobe signals DQS_t and DQS_c may be a differential pair of data strobe signals having a 180° phase relationship. The first IWL circuit 202 may be dedicated to performing internal write leveling operations. Thus, the first IWL circuit 202 may be used exclusively for an internal write leveling operation.

In addition, the memory device 200 may include a second IWL circuit 204 configured to evaluate the timing relationship between the pair of data strobe signals DQS_t and DQS_c and the write command signal WR according to a second IWL scheme, and generate a second IWL result signal R2 indicating whether the timing relationship satisfies a second IWL condition. Here, the second IWL scheme is different from the first IWL scheme. In addition, the first IWL condition may be different from the second IWL condition.

The first IWL circuit 202 and the second IWL circuit 204 may be provided in different voltage domains. For example, the first IWL circuit 202 may be provided in a first voltage domain (e.g., VPERI), and the second IWL circuit 204 may be provided in a second voltage domain (e.g., VDQS). The second voltage domain may be a same voltage domain in which a write operation is performed. Thus, the first IWL circuit 202 and the second IWL circuit 204 may operate according to different voltage supply levels.

The second IWL circuit 204 may be used for a same internal write leveling operation during which the first IWL circuit 202 is active. In other words, the first IWL circuit 202 and the second IWL circuit 204 may operate in parallel during the same internal write leveling operation to generate the first IWL result signal R1 and the second IWL result signal R2. Additionally, the second IWL circuit 204 may be used for a memory write operation (e.g., in normal write operations), for example, after one or more delay settings have been configured by the controller based on the internal write leveling operation.

In addition, the memory device 200 may include a combining circuit 206 configured to receive the first IWL result signal R1 and the second IWL result signal R2, and generate a final IWL result signal R3 indicating whether the timing relationship satisfies both the first IWL condition and the second IWL condition.

The combining circuit 206 may be an AND gate that generates a logic high signal level when the first IWL result signal R1 and the second IWL result signal R2 indicate that the timing relationship satisfies the first IWL condition and the second IWL condition, respectively. In contrast, the AND gate may generate a logic low signal level when the first IWL result signal R1 and/or the second IWL result signal R2 indicate that the timing relationship does not satisfy one or both of the first IWL condition and the second IWL condition. The final IWL result signal R3 may be provided to a controller, which may determine, based on the final IWL result signal R3, an optimal IWL setting, such as an optical delay setting. For example, in response to receiving a logic low signal level, the controller may adjust a timing of the pair of data strobe signals DQS_t and DQS_c and reassess the timing relationship based on the adjusted timing. On the other hand, in response to receiving a logic high signal level, the controller may use a current timing setting of the pair of data strobe signals DQS_t and DQS_c as a basis for the optical delay setting.

The memory device 200 may further include an input buffer 208 for the pair of data strobe signals DQS_t and DQS_c, and DQS gating logic 210. The input buffer 208 may receive the pair of data strobe signals DQS_t and DQS_c and provide ungated data strobe signals DS and DSF to the DQS gating logic 210. The ungated data strobe signals DS and DSF have a 180° phase relationship, and may be referred to as a pair of ungated data strobe signals DS and DSF that includes a first data strobe signal DS and a second data strobe signal DSF that is complementary to the first data strobe signal DS.

The DQS gating logic 210 may receive the pair of ungated data strobe signals DS and DSF and the write command signal WR. The DQS gating logic 210 may gate the first data strobe signal DS based on the write command signal WR to generate a first gated data strobe signal gatedDS having a first number of captured pulses. In other words, the gating logic may capture the first number of captured pulses of the first data strobe signal DS based on a gating of the first data strobe signal DS by the write command signal WR. Thus, the write command signal WR serves as a gating signal. In addition, the DQS gating logic 210 may gate the second data strobe signal DSF based on the write command signal WR to generate a second gated data strobe signal gatedDSF having a second number of captured pulses. In other words, the gating logic may capture the second number of captured pulses of the second data strobe signal DSF based on a gating of the second data strobe signal DSF by the write command signal WR.

The first IWL circuit 202 may determine whether the first number of captured pulses of the first gated data strobe signal gatedDS matches an expected number of captured pulses, determine whether the second number of captured pulses of the second gated data strobe signal gatedDSF matches the expected number of captured pulses, and indicate whether the timing relationship satisfies a first IWL condition based on the first number of captured pulses and the second number of captured pulses matching the expected number of captured pulses.

The expected number of captured pulses may correspond to a write preamble setting (WPRE) of the pair of data strobe signals. For example, if the memory device 200 is configured with a write preamble setting WPRE2/3, the pair of data strobe signals DQS_t and DQS_c may each be transmitted with two pulses (e.g., N=2, where N is a number of transmitted pulses). If the timing relationship between a data strobe signal and a pulse of the write command signal WR is satisfactory, the DQS gating logic 210 should be able to gate based on a first pulse and capture subsequent pulses. Thus, the expected number of captured pulses may be equal to 1, or N−1. On the other hand, if the timing relationship between a data strobe signal and a pulse of the write command signal WR is unsatisfactory, the DQS gating logic 210 may miss gating on the first pulse and instead gate on the second pulse. In the case of gating on the second pulse, there would be no captured pulses since only two pulses have been transmitted.

If the memory device 200 is configured with a write preamble setting WPRE4, the pair of data strobe signals DQS_t and DQS_c may each be transmitted with three pulses (e.g., N=3). If the timing relationship between a data strobe signal and a pulse of the write command signal WR is satisfactory, the DQS gating logic 210 should be able to gate based on a first pulse and capture subsequent pulses. Thus, the expected number of captured pulses may be equal to 2, or N−1. On the other hand, if the timing relationship between a data strobe signal and a pulse of the write command signal WR is unsatisfactory, the DQS gating logic 210 may miss gating on the first pulse and instead gate on the second pulse. In the case of gating on the second pulse, there would be only one captured pulse (e.g., the third pulse).

The first IWL circuit 202 may indicate whether the first number of captured pulses matches an expected number of captured pulses (e.g., by indications 211 and 212), indicate whether the second number of captured pulses matches the expected number of captured pulses (e.g., by indications 213 and 214), and generate the first IWL result signal R1 indicating whether the timing relationship between the pair of data strobe signals and the write command signal satisfies the first IWL condition based on the first number of captured pulses and the second number of captured pulses matching the expected number of captured pulses. Indications 211 and 213 may correspond to the expected number of captured pulses being configured for the write preamble setting WPRE2/3, and indications 212 and 214 may correspond to the expected number of captured pulses being configured for the write preamble setting WPRE4. Thus, the first IWL circuit 202 may determine that the timing relationship satisfies the first IWL condition in response to the first number of captured pulses and the second number of captured pulses matching the expected number of captured pulses, where the expected number of captured pulses is configured based on the write preamble setting.

The second IWL circuit 204 may determine whether the first number of captured pulses of the first gated data strobe signal gatedDS matches the expected number of captured pulses, determine whether the second number of captured pulses of the second gated data strobe signal gatedDSF matches the expected number of captured pulses, and indicate whether the timing relationship satisfies the second IWL condition based on at least one of the first number of captured pulses or the second number of captured pulses matching the expected number of captured pulses. Thus, the second IWL circuit 204 may indicate whether the first number of captured pulses matches the expected number of captured pulses (e.g., by indications 215 and 216), indicate whether the second number of captured pulses matches the expected number of captured pulses (e.g., by indications 217 and 218), and generate the second IWL result signal R2 indicating whether the timing relationship satisfies the second IWL condition based on at least one of the first number of captured pulses or the second number of captured pulses matching the expected number of captured pulses. Indications 215 and 217 may correspond to the expected number of captured pulses being configured for the write preamble setting WPRE2/3, and indications 216 and 218 may correspond to the expected number of captured pulses being configured for the write preamble setting WPRE4. Thus, the second IWL circuit 204 may determine that the timing relationship satisfies the second IWL condition in response to at least one of the first number of captured pulses or the second number of captured pulses matching the expected number of captured pulses, where the expected number of captured pulses is configured based on the write preamble setting.

The second IWL circuit 204 may include a 4-phase divider 220 that divides the first gated data strobe signal gatedDS and the second gated data strobe signal gatedDSF into two respective signals. The second IWL circuit 204 may further include a first burst counter 222 configured to indicate whether the first number of captured pulses matches the expected number of captured pulses, and a second burst counter 224 configured to indicate whether the second number of captured pulses matches the expected number of captured pulses. For example, the first burst counter 222 may include a first plurality of flip-flops 226 coupled in series and configured to count the first number of captured pulses and provide a first indication (e.g., indication 215 or indication 216) of whether the first number of captured pulses matches the expected number of captured pulses. If the first gated data strobe signal gatedDS has been properly gated, then indication 215 or indication 216 should indicate that the expected number of captured pulses has been captured. However, if the first gated data strobe signal gatedDS has not been properly gated due to the timing relationship being unsatisfactory, then indication 215 or indication 216 may not be triggered.

Furthermore, the second burst counter 224 may include a second plurality of flip-flops 228 coupled in series and configured to count the second number of captured pulses and provide a second indication (e.g., indication 217 or indication 218) of whether the second number of captured pulses matches the expected number of captured pulses. If the second gated data strobe signal gatedDSF has been properly gated, then indication 217 or indication 218 should indicate that the expected number of captured pulses has been captured. However, if the second gated data strobe signal gatedDSF has not been properly gated due to the timing relationship being unsatisfactory, then indication 217 or indication 218 may not be triggered.

The second IWL circuit 204 may include OR logic, including OR gate 230 and OR gate 232. OR gate 230 may be coupled to an output of a first flip-flop of the first burst counter 222 and to an output of a first flip-flop of the second burst counter 224. Thus, OR gate 230 may receive indications 215 and 217, and may correspond to the expected number of captured pulses being configured for the write preamble setting WPRE2/3. Thus, OR gate 230 may output a logic high signal level when at least one of the first number of captured pulses or the second number of captured pulses matches the expected number of captured pulses, as indicated by indication 215 or indication 217. The output of the OR gate 230 may be used as the second IWL result signal R2 when the memory device 200 is configured based on the write preamble setting WPRE2/3. Thus, the OR gate 230 may generate the second IWL result signal R2.

OR gate 232 may be coupled to an output of a second flip-flop of the first burst counter 222 and to an output of a second flip-flop of the second burst counter 224. Thus, OR gate 232 may receive indications 216 and 218, and may correspond to the expected number of captured pulses being configured for the write preamble setting WPRE4. Thus, OR gate 232 may output a logic high signal level when at least one of the first number of captured pulses or the second number of captured pulses matches the expected number of captured pulses, as indicated by indication 216 or indication 218. The output of the OR gate 232 may be used as the second IWL result signal R2 when the memory device 200 is configured based on the write preamble setting WPRE4. Thus, the OR gate 232 may generate the second IWL result signal R2.

As described above, the expected number of captured pulses may correspond to the write preamble setting of the pair of data strobe signals DQS_t and DQS_c. The first IWL circuit 202 may include a first multiplexer 234 that may select a first input from at least two first inputs based on the WPRE, and output the first input as the first IWL result signal R1. Thus, the output of the first multiplexer 234 may correspond to the WPRE. In addition, the second IWL circuit 204 may include a second multiplexer 236 that may select a second input from at least two second inputs based on the WPRE, and output the second input as the second IWL result signal R2. Thus, the output of the second multiplexer 236 may correspond to the WPRE.

A flip-flop 238 may output the final IWL result signal R3 to the controller based on an IWL detection latch. The controller may be coupled to a data output DQout of the memory device 200.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

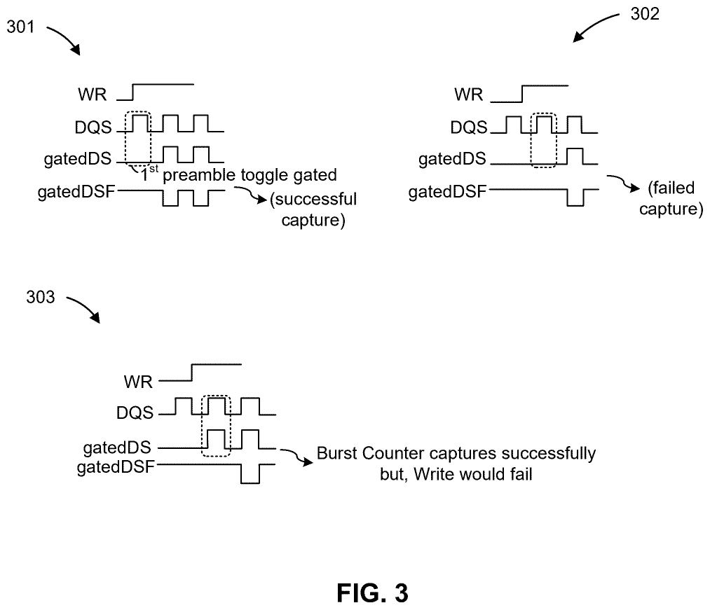

FIG. 3 shows diagrams 301, 302, and 303 of pulse captures according to one or more implementations.

Diagram 301 shows a successful gating of a data strobe signal DQS performed by DQS gating logic 210 which will match the expectation of the first IWL circuit 202 according to the write preamble setting WPRE4. Thus, both the first gated data strobe signal gatedDS and the second gated data strobe signal gatedDSF have a number of captured pulses that is equal to the expected number of captured pulses (e.g., 2).

Diagram 302 shows an unsuccessful gating of a data strobe signal DQS performed by DQS gating logic 210 which will not match the expectation of the first IWL circuit 202 according to the write preamble setting WPRE4. Thus, both the first gated data strobe signal gatedDS and the second gated data strobe signal gatedDSF have a number of captured pulses that is less than the expected number of captured pulses (e.g., 2), indicating a failed capture of the expected number of captured pulses.

Diagram 303 shows a partially successful gating of a data strobe signal DQS performed by DQS gating logic 210 for which first gated data strobe signal gatedDS will match the expectation of the second IWL circuit 204 according to the write preamble setting WPRE4. However, the second gated data strobe signal gatedDSF will not match the expectation of the second IWL circuit 204 according to the write preamble setting WPRE4 In this example, the first gated data strobe signal gatedDS has a number of captured pulses that is equal to the expected number of captured pulses (e.g., 2). However, the second gated data strobe signal gatedDSF has a number of captured pulses that is less than the expected number of captured pulses. Thus, the second IWL circuit 204 would indicate that the second IWL condition is satisfied based on at least one of the first gated data strobe signal gatedDS or the second gated data strobe signal gatedDSF matching the expected number of captured pulses. However, a write operation would fail, since the second gated data strobe signal gatedDSF has an incorrect number of captured pulses. In this case, the first IWL circuit 202 may indicate that the second gated data strobe signal gatedDSF has an incorrect number of captured pulses by indicating that the first IWL condition is not satisfied. Thus, the memory device 200 provides diverse IWL circuitry that may improve the accuracy of an IWL operation.

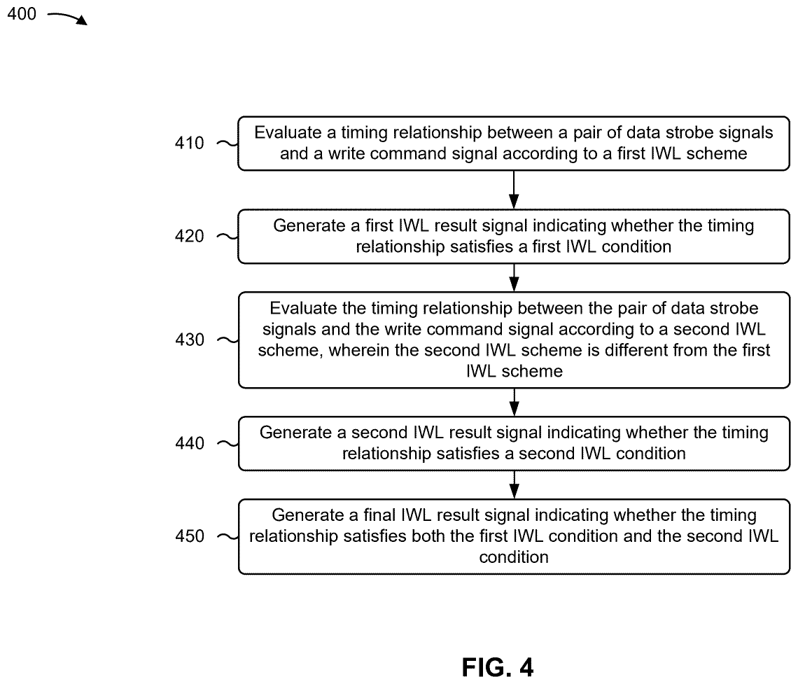

FIG. 4 is a flowchart of an example method 400 associated with an enhanced DDR IWL scheme. In some implementations, a memory device (e.g., the memory device 120) may perform or may be configured to perform the method 400. In some implementations, another device or a group of devices separate from or including the memory device (e.g., the memory system 110) may perform or may be configured to perform the method 400. Additionally, or alternatively, one or more components of the memory device (e.g., the memory system controller 115) may perform or may be configured to perform at least part of the method 400. Thus, means for performing the method 400 may include the memory device and/or one or more components of the memory device. Additionally, or alternatively, a non-transitory computer-readable medium may store one or more instructions that, when executed by the memory system, cause the memory device to perform the method 400.

As shown in FIG. 4, the method 400 may include evaluating a timing relationship between a pair of data strobe signals and a write command signal according to a first IWL scheme (block 410). As further shown in FIG. 4, the method 400 may include generating a first IWL result signal indicating whether the timing relationship satisfies a first IWL condition (block 420). As further shown in FIG. 4, the method 400 may include evaluating the timing relationship between the pair of data strobe signals and the write command signal according to a second IWL scheme, wherein the second IWL scheme is different from the first IWL scheme (block 430). As further shown in FIG. 4, the method 400 may include generating a second IWL result signal indicating whether the timing relationship satisfies a second IWL condition (block 440). As further shown in FIG. 4, the method 400 may include generating a final IWL result signal indicating whether the timing relationship satisfies both the first IWL condition and the second IWL condition (block 450).

The method 400 may include additional aspects, such as any single aspect or any combination of aspects described below and/or described in connection with one or more other methods or operations described elsewhere herein.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory device comprises: a first IWL circuit configured to evaluate a timing relationship between a pair of data strobe signals and a write command signal according to a first IWL scheme, and generate a first IWL result signal indicating whether the timing relationship satisfies a first IWL condition; a second IWL circuit configured to evaluate the timing relationship between the pair of data strobe signals and the write command signal according to a second IWL scheme, and generate a second IWL result signal indicating whether the timing relationship satisfies a second IWL condition, wherein the second IWL scheme is different from the first IWL scheme; and a combining circuit configured to receive the first IWL result signal and the second IWL result signal, and generate a final IWL result signal indicating whether the timing relationship satisfies both the first IWL condition and the second IWL condition.

In some implementations, a memory device comprises: gating logic configured to receive a pair of data strobe signals and a write command signal, wherein the pair of data strobe signals includes a first data strobe signal and a second data strobe signal that is complementary to the first data strobe signal, wherein the gating logic is configured to capture a first number of captured pulses of the first data strobe signal based on a gating of the first data strobe signal by the write command signal, wherein the gating logic is configured to capture a second number of captured pulses of the second data strobe signal based on a gating of the second data strobe signal by the write command signal; a first IWL circuit is configured to indicate whether the first number of captured pulses matches an expected number of captured pulses, indicate whether the second number of captured pulses matches the expected number of captured pulses, and generate a first IWL result signal indicating whether a timing relationship between the pair of data strobe signals and the write command signal satisfies a first IWL condition based on the first number of captured pulses and the second number of captured pulses matching the expected number of captured pulses; a second IWL circuit is configured to indicate whether the first number of captured pulses matches the expected number of captured pulses, indicate whether the second number of captured pulses matches the expected number of captured pulses, and generate a second IWL result signal indicating whether the timing relationship satisfies a second IWL condition based on at least one of the first number of captured pulses or the second number of captured pulses matching the expected number of captured pulses; and a combining circuit configured to receive the first IWL result signal and the second IWL result signal, and generate a final IWL result signal indicating whether the timing relationship satisfies both the first IWL condition and the second IWL condition.

In some implementations, a method of performing an internal write leveling operation includes evaluating, by a first IWL circuit, a timing relationship between a pair of data strobe signals and a write command signal according to a first IWL scheme; generating, by the first IWL circuit, a first IWL result signal indicating whether the timing relationship satisfies a first IWL condition; evaluating, by a second IWL circuit, the timing relationship between the pair of data strobe signals and the write command signal according to a second IWL scheme, wherein the second IWL scheme is different from the first IWL scheme; generating, by the second IWL circuit, a second IWL result signal indicating whether the timing relationship satisfies a second IWL condition; and generating, by a combining circuit, a final IWL result signal indicating whether the timing relationship satisfies both the first IWL condition and the second IWL condition.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising;
a first internal write leveling (IWL) circuit configured to evaluate a timing relationship between a pair of data strobe signals and a write command signal according to a first IWL scheme, and generate a first IWL result signal indicating whether the timing relationship satisfies a first IWL condition;
a second IWL circuit configured to evaluate the timing relationship between the pair of data strobe signals and the write command signal according to a second IWL scheme, and generate a second IWL result signal indicating whether the timing relationship satisfies a second IWL condition, wherein the second IWL scheme is different from the first IWL scheme; and
a combining circuit configured to receive the first IWL result signal and the second IWL result signal, and generate a final IWL result signal indicating whether the timing relationship satisfies both the first IWL condition and the second IWL condition.

2. The memory device of claim 1, wherein the first IWL condition is different from the second IWL condition.

3. The memory device of claim 1, wherein the first IWL circuit is used exclusively for an internal write leveling operation, and
wherein the second IWL circuit is used for the internal write leveling operation and for a memory write operation.

4. The memory device of claim 1, wherein the pair of data strobe signals is a differential pair of data strobe signals having a 180° phase relationship.

5. The memory device of claim 1, wherein the memory device is a dynamic random-access memory (DRAM) memory chip.

6. The memory device of claim 1, further comprising:
gating logic configured to receive the pair of data strobe signals and the write command signal, wherein the pair of data strobe signals includes a first data strobe signal and a second data strobe signal that is complementary to the first data strobe signal,
wherein the gating logic is configured to gate the first data strobe signal based on the write command signal to generate a first gated data strobe signal having a first number of captured pulses,
wherein the gating logic is configured to gate the second data strobe signal based on the write command signal to generate a second gated data strobe signal having a second number of captured pulses, and
wherein the first IWL circuit is configured to determine whether the first number of captured pulses of the first gated data strobe signal matches an expected number of captured pulses, determine whether the second number of captured pulses of the second gated data strobe signal matches the expected number of captured pulses, and indicate whether the timing relationship satisfies a first IWL condition based on the first number of captured pulses and the second number of captured pulses matching the expected number of captured pulses.

7. The memory device of claim 6, wherein the expected number of captured pulses corresponds to a write preamble setting of the pair of data strobe signals.

8. The memory device of claim 6, wherein the second IWL circuit is configured to determine whether the first number of captured pulses of the first gated data strobe signal matches the expected number of captured pulses, determine whether the second number of captured pulses of the second gated data strobe signal matches the expected number of captured pulses, and indicate whether the timing relationship satisfies the second IWL condition based on at least one of the first number of captured pulses or the second number of captured pulses matching the expected number of captured pulses.

9. The memory device of claim 8, wherein the expected number of captured pulses corresponds to a write preamble setting of the pair of data strobe signals,
wherein the first IWL circuit includes a first multiplexer configured to select a first input from at least two first inputs based on the write preamble setting, and output the first input as the first IWL result signal, and
wherein the second IWL circuit includes a second multiplexer configured to select a second input from at least two second inputs, and output the second input as the second IWL result signal.

10. The memory device of claim 1, further comprising:
gating logic configured to receive the pair of data strobe signals and the write command signal, wherein the pair of data strobe signals includes a first data strobe signal and a second data strobe signal that is complementary to the first data strobe signal,
wherein the gating logic is configured to gate the first data strobe signal based on the write command signal to generate a first gated data strobe signal having a first number of captured pulses,
wherein the gating logic is configured to gate the second data strobe signal based on the write command signal to generate a second gated data strobe signal having a second number of captured pulses, and
wherein the second IWL circuit is configured to determine whether the first number of captured pulses of the first gated data strobe signal matches an expected number of captured pulses, determine whether the second number of captured pulses of the second gated data strobe signal matches the expected number of captured pulses, and indicate whether the timing relationship satisfies a second IWL condition based on at least one of the first number of captured pulses or the second number of captured pulses matching the expected number of captured pulses.

11. The memory device of claim 10, wherein the second IWL circuit comprises:
a first burst counter configured to indicate whether the first number of captured pulses matches the expected number of captured pulses;
a second burst counter configured to indicate whether the second number of captured pulses matches the expected number of captured pulses; and
OR logic coupled to the first burst counter and the second burst counter, and configured to generate the second IWL result signal.

12. The memory device of claim 11, wherein the second IWL circuit comprises:
wherein the first burst counter includes a first plurality of flip-flops coupled in series and configured to count the first number of captured pulses and provide a first indication of whether the first number of captured pulses matches the expected number of captured pulses, and
wherein the second burst counter includes a second plurality of flip-flops coupled in series and configured to count the second number of captured pulses and provide a second indication of whether the second number of captured pulses matches the expected number of captured pulses.

13. The memory device of claim 10, wherein the second IWL circuit comprises:
a first burst counter configured to count the first number of captured pulses; and
a second burst counter configured to count the second number of captured pulses; and
OR logic coupled to the first burst counter and the second burst counter, and configured to generate the second IWL result signal.

14. The memory device of claim 1, wherein the combining circuit is an AND gate.

15. The memory device of claim 1, wherein the first IWL circuit is provided in a first voltage domain, and the second IWL circuit is provided in a second voltage domain that is different from the first voltage domain.

16. A memory device, comprising;
gating logic configured to receive a pair of data strobe signals and a write command signal, wherein the pair of data strobe signals includes a first data strobe signal and a second data strobe signal that is complementary to the first data strobe signal,
wherein the gating logic is configured to capture a first number of captured pulses of the first data strobe signal based on a gating of the first data strobe signal by the write command signal,
wherein the gating logic is configured to capture a second number of captured pulses of the second data strobe signal based on a gating of the second data strobe signal by the write command signal;
a first internal write leveling (IWL) circuit is configured to indicate whether the first number of captured pulses matches an expected number of captured pulses, indicate whether the second number of captured pulses matches the expected number of captured pulses, and generate a first IWL result signal indicating whether a timing relationship between the pair of data strobe signals and the write command signal satisfies a first IWL condition based on the first number of captured pulses and the second number of captured pulses matching the expected number of captured pulses;
a second IWL circuit is configured to indicate whether the first number of captured pulses matches the expected number of captured pulses, indicate whether the second number of captured pulses matches the expected number of captured pulses, and generate a second IWL result signal indicating whether the timing relationship satisfies a second IWL condition based on at least one of the first number of captured pulses or the second number of captured pulses matching the expected number of captured pulses; and
a combining circuit configured to receive the first IWL result signal and the second IWL result signal, and generate a final IWL result signal indicating whether the timing relationship satisfies both the first IWL condition and the second IWL condition.

17. The memory device of claim 16, wherein the first IWL circuit is configured to determine that the timing relationship satisfies the first IWL condition in response to the first number of captured pulses and the second number of captured pulses matching the expected number of captured pulses, and
wherein the second IWL circuit is configured to determine that the timing relationship satisfies the second IWL condition in response to at least one of the first number of captured pulses or the second number of captured pulses matching the expected number of captured pulses.

18. The memory device of claim 16, wherein the first IWL circuit is used exclusively for an internal write leveling operation, and
wherein the second IWL circuit is used for the internal write leveling operation and for a memory write operation.

19. The memory device of claim 16, wherein the second IWL circuit comprises:
a first burst counter configured to indicate whether the first number of captured pulses matches the expected number of captured pulses;
a second burst counter configured to indicate whether the second number of captured pulses matches the expected number of captured pulses; and
OR logic coupled to the first burst counter and the second burst counter, and configured to generate the second IWL result signal.

20. A method of performing an internal write leveling operation, the method comprising:
evaluating, by a first internal write leveling (IWL) circuit, a timing relationship between a pair of data strobe signals and a write command signal according to a first IWL scheme;
generating, by the first IWL circuit, a first IWL result signal indicating whether the timing relationship satisfies a first IWL condition;
evaluating, by a second IWL circuit, the timing relationship between the pair of data strobe signals and the write command signal according to a second IWL scheme, wherein the second IWL scheme is different from the first IWL scheme;
generating, by the second IWL circuit, a second IWL result signal indicating whether the timing relationship satisfies a second IWL condition; and
generating, by a combining circuit, a final IWL result signal indicating whether the timing relationship satisfies both the first IWL condition and the second IWL condition.
